(19) United States
(12) Patent Application Publication
(10) Pub. No.: US 2026/0043840 A1
(43) Pub. Date: Feb. 12, 2026

(54) HANDHELD DEVICE FOR THE DETECTION OF ELECTROSTATIC DISCHARGE

(71) Applicant: Roche Diagnostics GmbH, Mannheim (DE)

(72) Inventor: Sandra Kilian, Kirchseeon (DE)

(21) Appl. No.: 19/361,530

(22) Filed: Oct. 17, 2025

Related U.S. Application Data
(63) Continuation of application No. PCT/EP2024/059905, filed on Apr. 11, 2024.

(30) Foreign Application Priority Data
Apr. 20, 2023 (EP) 23168961.3

(51) Int. Cl. G01R 31/12; G01R 31/16

(52) U.S. Cl. CPC G01R 31/1281; G01R 31/16

(57) ABSTRACT

The present invention is directed to a handheld device for the detection of electrostatic discharge, comprising an evaluation unit, and a cable antenna, wherein the cable antenna is formed in a coil-like manner with a number n of windings, with n≥2, each winding being wound around a winding axis, a diameter of each winding is less than 30 cm, and the windings of the cable antenna are spaced apart from each other, preferably by means of at least one spacer.

### TECHNICAL FIELD

Generally, the present invention relates to the technical field of detecting electrostatic fields in a measuring object, for example within a vessel such as a chemical reactor. In particular, the present invention is directed to a handheld device for detecting electrostatic discharge within such reactor, in which often electrostatic charges and, thus, electrostatic discharges (“ESD”) can occur, due to the processing of liquids and/or suspensions with low conductivity. The invention also relates to the use of such handheld device.

### BACKGROUND

In the past, steel-enamelled vessels have been the common choice as reactor for carrying out, for example, the production of chemicals or the like. During such chemical production, in which often liquids and/or suspensions of low conductivity are processed by e.g. stirring, electrostatic charges and, often in consequence, electrostatic discharges occur. However, due to the fact that the processing for chemical production sometimes generates combustible gases, i.e. an explosive atmosphere within the headspace of the used respective chemical reactor can occur, any kind of ignition of such explosive atmosphere is to be avoided. For example, an electrostatic discharge can be an ignition source for the explosive atmosphere and result in an explosion, which can have severe consequences not only for the chemical production and the employees but also for the vessel itself, such as a disruptive discharge penetrating the enamel of the steel-enamelled wall of the vessel.

To avoid such problems, several industrial solutions have been suggested in the past, which mostly aim to avoid the generation of a flammable atmosphere, essentially meaning charging liquids or powders to an inerted atmosphere, or to avoid the generation of any kind of ignition source, i.e. avoiding presence of elements and conditions that can generate an ignition source. However, such solutions can either not be implemented or only with a great effort in the course of chemical production, due to the liquids to be used and the requirements of the respective vessel, e.g. its material properties. Therefore, an available measuring technique is desired for the assessment of the probability of occurrence of ignition sources in form of potential electrostatic ignition for such vessels and for determining explosion protective measures.

In view of the above, a measuring system for measurement of electric charge in turbulent material flowing through a pipe, in order to find out the risk of explosions within the material, has been suggested in U.S. Pat. No. 3,753,102. Variations in the electric charge of the turbulent material which flows past an electrode are measured with an AC voltage meter, wherein the AC component induced by the changes in the electric field is conducted directly via an AC amplifier and a rectifier to a DC voltage meter. U.S. Pat. No. 5,151,659 discloses a similar measuring system with direct measurement of electric charges, in this case induced in rapidly oscillating electrodes arranged in a protecting opening in front of the surface the charge of which is to be measured. However, in regard to the proposed solutions of these cases, the measurement methods cannot be used to determine electrostatic discharge within a chemical reactor, since its integrity cannot be compromised. Also, the measurement results are easily affected by interference due to the sensitivity of the respective measuring method.

As a further approach, in order to prevent ignition of the explosive atmosphere, it has also been suggested to make the inside of the reactor inert in order to completely avoid the occurrence of electrostatic discharges during operation. However, the requirements for making such reactor electrically inert are complex and costly. As an alternative solution, it has been proposed to exchange the commonly used steel-enamelled vessels by a steel-enamelled vessel with platinum fibers provided in the enamel layer. Due to the lower volume resistivity of such coating, it is assumed that the material to be stirred within the reactor should be less charged, or the inner walls of the reactor should be enabled to easier discharge any kind of occurring electrostatic charge. These desired effects, however, must be tested and/or confirmed first, in order to avoid any undesired effects or results. For such tests, it has been currently suggested in the present technical field, see for example Alexis Pey, Martin Glor, “Charging powders in vessels with flammable vapour atmospheres. An industrial approach”, Journal of Electrostatics, Volume 117, 2022, 103695, ISSN 0304-3886, to detect tuft discharges with a loop antenna with a diameter of at least 700 mm, which antenna was mounted into the vessel before the material to be stirred was charged into the vessel. Here, the mentioned diameter size is the minimum diameter size required to be able to correctly detect any electrostatic discharge within the vessel. However, since chemical production does not always occur in large-size vessels, such as vessels with a volume of 100 l to 1000 l, but can also be carried out in vessels with a small size, such as vessels with a volume of less than 30 l, the suggested loop antenna cannot be used in such small vessels. In addition, the suggested loop antenna is difficult to transport due to its large size.

Accordingly, it is the object of the present invention to provide a solution for measuring the frequency of occurrence of electrostatic discharge, and, thereby, confirming the usability of new designs of small volume reactors for chemical production in regard to explosion prevention, with the focus on reducing the requirements for inerting the reactor.

### SUMMARY OF THE INVENTION

The present invention addresses the above described problems of evaluating the usability of new vessel designs for chemical production reactors, in particular in regard to the avoidance of electrostatic discharges. According to a first aspect of the present invention, a handheld device for the detection of electrostatic discharge is suggested, the handheld device comprising an evaluation unit and a cable antenna, wherein the cable antenna, which can also be provided in the form of a probe, is formed in a coil-like manner with a number n of windings, with n≥2, and with each winding being wound around a winding axis. Here, the winding axis can be a common winding axis, i.e. one winding axis common to all windings. Alternatively, the windings can comprise different winding axes arranged in parallel to each other, but not arranged in a coaxial manner. Further, a diameter of each winding of the coil-like cable antenna of the handheld device is less than 30 cm, and the windings of the cable antenna are spaced apart from each other, wherein such spacing apart can be implemented by means of at least one spacer. With the use of a coil-like antenna, it can be avoided to use an antenna with a large diameter, in order to maintain a small and, thus, handheld size of the device. Accordingly, the diameter, to be exact the perimeter of the cable antenna can be compensated by the number of windings, also referred to as turns. Thus, by applying more windings, a smaller diameter of the cable antenna can be achieved, along with maintaining the reliable detection of electrostatic discharges. The higher the number of windings/turns, the more sensitive the detection of the discharge, i.e. the higher the amplitude of the measurement signal.

According to a specific embodiment, the number n of windings of the cable antenna of the handheld device of the present invention complies with n>2, wherein the number n of windings can comply with 3≤n≤11. In this regard, it is pointed out that the number of windings can affect the detectable representation of the measurement result. In further detail, a larger number of windings of the cable antenna of the handheld device of the present invention can result in a significant stretch of the duration of discharge displayed on a meter or display, when comparing detections of the same discharge type. Here, the discharge can be displayed as an oscillation with positive and negative amplitude, which decreases. The higher the number of turns, the more a decreasing amplitude can be observed, which is why the discharge duration visible on the meter increases. In addition, by using a cable antenna with a high number of windings, electrostatic discharges can be detected with certainty even with small winding diameters. Thus, the cable antenna of the handheld device of the present invention can be used particularly in all kinds of reactor vessels of small size, i.e. in a multifunctional manner depending on the number of windings. Furthermore, a measuring sensitivity of the cable antenna of the handheld device of the present invention can be increased with increasing the number of windings, wherein, since background noise generally exists with such measurement techniques, a compromise must be made in regard to the chosen number of windings, between the degree of sensitivity and the avoidance of capturing background noise by means of the used form of evaluation unit. Another advantage due to the compact size of the handheld device of the present invention is its improved transportability due to the small size of the cable antenna.

According to a specific embodiment of the handheld device of the present invention, a diameter of each winding of the cable antenna of the handheld device is about 5 cm, wherein the diameters of adjacent windings of the cable antenna of the handheld device of the present invention can differ from each other. Thus, the diameters of the windings of the cable antenna do not have to be identical with each other but can be smaller or larger than the other, i.e. the diameter of one winding can be smaller or larger than the diameter of an adjacent winding. Further, all windings of the cable antenna of the handheld device of the present invention can exhibit a winding shape consistent with each other, wherein the winding shape of the cable antenna is chosen from the group of shapes consisting of circular, elliptical, triangular, or square, i.e. the winding shape of the cable antenna can be a circular shape, elliptical shape, triangular shape, square shape, polygonal shape, or a shape exhibiting any combination of the previously listed shapes. Accordingly, the windings of the cable antenna of the handheld device of the present invention do not have to be round, but can also exhibit another shape or combination of shapes as previously mentioned. Here again, it is pointed out that the structural geometry of the cable antenna of the handheld device of the present invention can affect the presentation of the measurement result.

According to a further specific embodiment of the handheld device of the present invention, each spacer, if any, is chosen in dimension so that it provides for a distance between the windings, which distance approximately corresponds to the outer cable diameter, i.e. the cable's outer diameter. This means that each spacer is chosen in dimension so that it provides for a distance between the windings similar or identical to the outer diameter of the cable of the cable antenna, wherein a distance “similar” to the cable's outer diameter resides within a range of ±20% of the diameter size, or within a range of ±10% of the diameter size. Alternatively or additionally, each spacer of the handheld device of the present invention is made of insulating material, such as plastic material, for example polyvinylchloride, polypropylene, or polytetrafluoroethylene, wherein Teflon™ can be cited as one specific material for such electrically insulating plastic material. Accordingly, with or without spacer, each winding is electrically insulated from the adjacent windings, either by means of the spacer or by air.

According to a further specific embodiment of the handheld device of the present invention, the windings of the cable antenna can be spaced apart from each other by means of at least two spacers, wherein such two spacers can be arranged in an opposing manner, i.e. the two spacers in such configuration are arranged on opposing sides of the antenna winding structure. Thereby, an even distribution of spacers across the diameter of the cable antenna can be achieved. Alternatively, the windings of the cable antenna of the handheld device of the present invention can be spaced apart from each other by means of at least three spacers, wherein the spacers can be arranged in an equidistant manner, i.e. the spacers are arranged so that each spacer provides for the same distance to each of its adjacent spacers. Again, an even distribution of spacers across the diameter of the cable antenna can be achieved. Alternatively, a distance between the windings can be achieved by providing a spacer material along the entire cable antenna, i.e. an insulating spacer material fills up all spacing between adjacent windings, thereby achieving a constant spacing between the windings. Accordingly, any configuration of spacers or provision of spacer material suffices as long as the distance between adjacent windings can be maintained in an insulating manner.

According to a further specific embodiment of the handheld device of the present invention, the cable antenna is made of a coaxial cable, i.e. a type of electrical cable consisting of an inner conductor surrounded by a concentric conductive hull, with the inner conductor and the conducting hull being separated by an insulating material, e.g. a dielectric material. With the cable antenna of the handheld device of the present invention being made of a coaxial cable, the inner conductor can comprise silver. For example, the inner conductor can be made of silver, or can be silver-plated, with any other suitable kind of inner core, such as copper or the like. Due to the good electrical conductivity of such coaxial cable using a silver or silver-plated inner conductor instead of, e.g. an inner conductor made purely of copper, only low measurement loss within the coaxial cable is occurring, thereby resulting in an improved measurement sensitivity of such cable antenna. In addition, the coaxial cable comprising the previously described structure with a silver inner conductor or a silver-plated inner conductor, thus, exhibits an improved durability and can endure higher mechanical load, due to improved mechanical strength of the inner conductor. In addition, the conductive hull can be made of a rigid or unflexible material, such as an iron sheet material, which adds to the mechanical strength, resulting in that no spacer is needed for achieving stable distance between adjacent windings. In case of the use of a flexible material for the conductive hull of the cable, the use of one or several spacers is advantageous for maintaining the distance between adjacent windings in an insulating manner.

According to a further specific embodiment of the handheld device of the present invention, the evaluation unit can comprise one or several of an oscilloscope, a display, a wireless communication module, such as a Bluetooth connection module or the like, and a network analyzer. In general, since any of these potential components of the handheld device of the present invention are either connectable and, thus, separatable to the cable antenna, or are rather small in general, the handheld device provides good transportability and good size for use in the hand.

According to a further specific embodiment of the handheld device of the present invention, the handheld device is configured for measurement in containers with a small inner volume, wherein the handheld device can be configured for measurement in containers with an inner volume of less than 30 l. Here, however, it is pointed out that not the volume but the length/diameter ratio is decisive, since a diameter of a container needs to be correspondingly larger, taking into account internal technical structures, such as flow breakers, agitators, and the like. According to a further specific embodiment of the handheld device of the present invention, the handheld device can be particularly configured for measurement in a reactor for chemical production, including all respective safety measures, wherein the chemical production can include the processing of suspensions of low conductivity, i.e. with κ<50 pS/m, resulting in the danger of high electrostatic discharges. However, the measurement in a reactor for chemical production is not limited to the processing of suspensions of low conductivity; suspensions of medium conductivity with 50 pS/m<κ≤10.000 pS/m as well as suspensions with high conductivity with 10.000 pS/m≤κ can also be processed and, thus, measured. Also, even though the device of the present invention is a handheld device, it can be used in a temporarily fixed manner, i.e. in stationary use, wherein the handheld device is used with a container, such as a reactor. In general, when used with a container, such as a reactor, the cable antenna is the part of the device that is arranged within the reactor, e.g. protruding through an opening from the outside to the inside of the reactor, whereas the evaluation unit and the like are left outside of the reactor. This also applies in the stationary use, such that the cable antenna is fixedly arranged within the reactor volume, whereas the evaluation unit is arranged outside of the reactor hull. Besides reactors, the handheld device of the present invention can be configured for measurement inside other kinds of containers or vessels, such as silos, which can include an explosive atmosphere, and in which electrostatic discharges can occur, e.g. chemical production or tank filling operations. Alternatively or additionally, the device can also be used in regard to the general flow of fluids and powders, or in the surrounding of charging processes, such as the movement of conveyor belts or plastic films, where an explosive atmosphere can occur.

According to a second aspect of the present invention, a use of a handheld device as described above is provided for the detection of electrostatic discharge in a surrounding containing an explosive atmosphere, such as in the surrounding of charging processes, e.g. at the site of movement of conveyor belts or plastic films, where an explosive atmosphere can occur. Therefore, the handheld device of the present invention can be used in a multifunctional manner in any atmosphere where an explosive atmosphere and electrostatic charge can occur in combination, even in small or poorly accessible spaces.

In addition, and in accordance to a third aspect of the present invention, a use of a handheld device as described above is provided for the detection of electrostatic discharge in a container with a volume of less than 30 l, such as a reactor for chemical production. In general, the handheld device of the present invention can be used for evaluation of a type of electrostatic discharge, such as brush discharge, spark discharge or corona discharge, and the probability of appearance and ignitability of the electrostatic discharges. Specifically, the handheld device of the present invention can be used for evaluation of ignitability of electrostatic discharges in different kinds of reactors, i.e. different in regard to their layout, material properties, and the like. According to a specific embodiment of such use of the handheld device of the present invention, the detection of electrostatic discharge can be carried out on demand, wherein demand usually exists when a charge-generating process is to be assumed during operation and its relevance in regard to the potential of ignition must be investigated in order to derive explosion protective measures. Alternatively, the detection of electrostatic discharge can be carried out continuously, for example with a sampling rate of 2 μs. Here, the sampling rate of 2 μs is suitable e.g. for the detection of brush discharges, whereas a duration of differing electrostatic discharges, such as spark discharges, is higher, i.e. up to 0.5 ms, resulting in a higher sampling rate for the detection of this particular type of discharge. In general, the sampling rate of the handheld device of the present invention depends on the number of windings. For example, with 11 windings a coarser sampling rate can be sufficient.

The above described device can be controlled by a control unit, wherein any kind of actuation or monitoring of the above described device and its components can also be controlled by such control unit. The term “control unit” as used herein encompasses any physical or virtual processing device, such as a CPU or the like, which can also control an entire workstation comprising one or more instruments in a way that workflow(s) and workflow step(s) can be conducted. The control unit may, for example, carry different kinds of application software and provide instructions to the device or a specific component thereof. The control unit may receive information from a data management unit regarding which steps need to be performed. Further, the control unit might be integral with a data management unit, may be comprised by a server computer and/or be part of one instrument or even distributed across multiple instruments of a respective processing system. The control unit may, for instance, be embodied as a programmable logic controller running a computer-readable program provided with instructions to perform operations. Here, in order to receive such instructions by a user, a user interface can additionally be provided, wherein the term “user interface” as used herein encompasses any suitable piece of application software and/or hardware for interactions between an operator and a machine, including but not limited to a graphical user interface for receiving as input a command from an operator and also to provide feedback and convey information thereto. Also, a system/device may expose several user interfaces to serve different kinds of users/operators.

As used herein and also in the appended claims, the singular forms “a”, “an”, and “the” include plural reference unless the context clearly dictates otherwise. Similarly, the words “comprise”, “contain” and “encompass” are to be interpreted inclusively rather than exclusively; that is to say, in the sense of “including, but not limited to”. Similarly, the word “or” is intended to include “and” unless the context clearly indicates otherwise. The terms “plurality”, “multiple” or “multitude” refer to two or more, i.e. 2 or >2, with integer multiples, wherein the terms “single” or “sole” refer to one, i.e. =1. Furthermore, the term “at least one” is to be understood as one or more, i.e. 1 or >1, also with integer multiples. Accordingly, words using the singular or plural number also include the plural and singular number, respectively. Additionally, the words “herein,” “above,”, “previously” and “below” and words of similar import, when used in this description, shall refer to this description as a whole and not to any particular portions of the description.

Furthermore, certain terms are used for reasons of convenience and are not intended to limit the invention. The terms “right”, “left”, “up”, “down”, “under” and “above” refer to directions in the figures. The terminology comprises the explicitly mentioned terms as well as their derivations and terms with a similar meaning. Also, spatially relative terms, such as “beneath”, “below”, “lower”, “above”, “upper”, “proximal”, “distal”, and the like, may be used to describe one element's or feature's relationship to another element or feature as illustrated in the figures. These spatially relative terms are intended to encompass different positions and orientations of the devices in use or operation in addition to the position and orientation shown in the figures. For example, if a device in the figures is turned over, elements described as “below” or “beneath” other elements or features would then be “above” or “over” the other elements or features. Thus, the exemplary term “below” can encompass both positions and orientations of above and below. The devices may be otherwise oriented (rotated 90 degrees or at other orientations), and the spatially relative descriptors used herein interpreted accordingly. Likewise, descriptions of movement along and around various axes include various special device positions and orientations.

To avoid repetition in the figures and the descriptions of the various aspects and illustrative embodiments, it should be understood that many features are common to many aspects and embodiments. The description of specific embodiments of the disclosure is not intended to be exhaustive or to limit the disclosure to the precise form disclosed. While the specific embodiments of, and examples for, the disclosure are described herein for illustrative purposes, various equivalent modifications are possible within the scope of the disclosure, as those skilled in the relevant art will recognize. Specific elements of any foregoing embodiments can be combined or substituted for elements in other embodiments. Furthermore, while advantages associated with certain embodiments of the disclosure have been described in the context of these embodiments, other embodiments may also exhibit such advantages, and not all embodiments need necessarily exhibit such advantages to fall within the scope of the disclosure as defined by the appended claims. Omission of an aspect from a description or figure does not imply that the aspect is missing from embodiments that incorporate that aspect. Instead, the aspect may have been omitted for clarity and to avoid prolix description. In this context, the following applies to the rest of this description: If, in order to clarify the drawings, a figure contains reference signs which are not explained in the directly associated part of the description, then it is referred to previous or following description sections. Further, for the reason of lucidity, if in a section of a drawing not all features of a part are provided with reference signs, it is referred to other sections of the same drawing. Like numbers in two or more figures represent the same or similar elements.

The following examples are intended to illustrate various specific embodiments of the present invention. As such, the specific modifications as discussed hereinafter are not to be construed as limitations on the scope of the present invention. It will be apparent to the person skilled in the art that various equivalents, changes, and modifications may be made without departing from the scope of the present invention, and it is thus to be understood that such equivalent embodiments are to be included herein. Also, features of the claimed device can be used for the claimed use, and vice versa. Further aspects and advantages of the present invention will become apparent from the following description of particular embodiments illustrated in the figures.

### BRIEF DESCRIPTION OF THE DRAWINGS

FIG. 1 is a conceptual illustration of a cable antenna of a handheld device according to an embodiment of the present invention; and

FIG. 2 is a conceptual illustration of a cable antenna of a handheld device according to an alternative embodiment of the present invention.

### LIST OF REFERENCE SIGNS

1 cable antenna, square-shaped
1′ cable antenna, circular-shaped
2 winding
2′ winding
21 conducting hull with inner insulating material
21′ conducting hull with inner insulating material
22 inner conductor
22′ inner conductor
3 distance between adjacent windings
3′ distance between adjacent windings
Øc diameter of square-shaped cable antenna
Øs diameter of circular-shaped cable antenna

### DETAILED DESCRIPTION

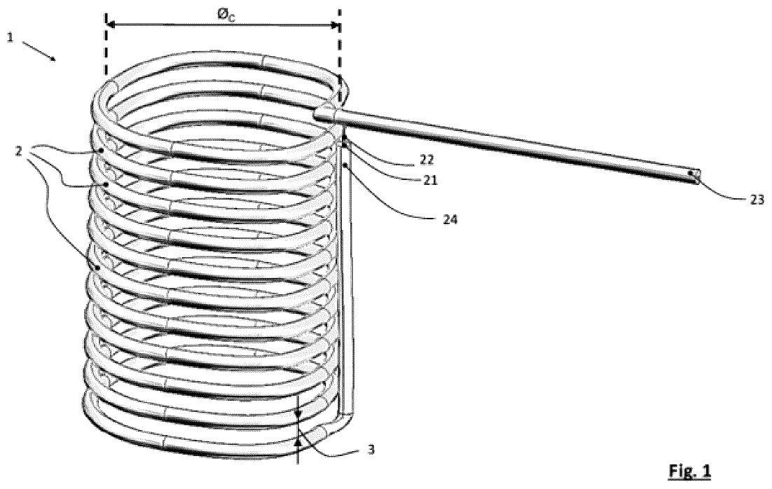

FIG. 1 shows a conceptual illustration of a cable antenna 1 of a handheld device according to an embodiment of the present invention, wherein the cable antenna 1 comprises 11 windings 2. Each winding 2 exhibits a similar circular shape, with a common diameter Øc of less than 30 cm, and with a common winding axis. In the embodiment as shown in FIG. 1, a stability provided by the mechanical properties of the cable antenna 1 is sufficient to maintain a constant distance 3 between two adjacent windings 2, without the necessity of a spacer. As can be gathered from FIG. 1, the distance 3 is identical or almost identical to the outer diameter of the cable antenna 1. The cable antenna 1 is implemented by a coaxial cable comprising, as an outer component, a conductive hull 21 surrounding an insulating material, in which an inner conductor 22 is embedded in a centralized manner, as inner core of the coaxial cable. The proximal end 23 of the cable antenna 1 is connected to an evaluation unit (not shown) of the handheld device of the presently described embodiment of the present invention. The distal portion of the cable antenna 1, including its distal end 24, proceeds towards the proximal portion of the cable antenna 1, which includes the proximal end 23, wherein the distal portion of the cable antenna 1 after concluding the winding progression extends parallel, or at least adjacent, to the winding axis of the windings 2, with direction towards the proximal portion of the cable antenna 1. Here, the distal portion of the cable antenna 1 is arranged at a distance spaced apart from the windings, in order to avoid any contact with the conductive hull 21 of the cable antenna 1 in the windings area. At the distal end 24 of the cable antenna 1, the inner conductor 22 then protrudes from the conductive hull 21 and from the insulating material, and connects to the conductive hull 21 at a location close to the proximal end 23 of the cable antenna 1.

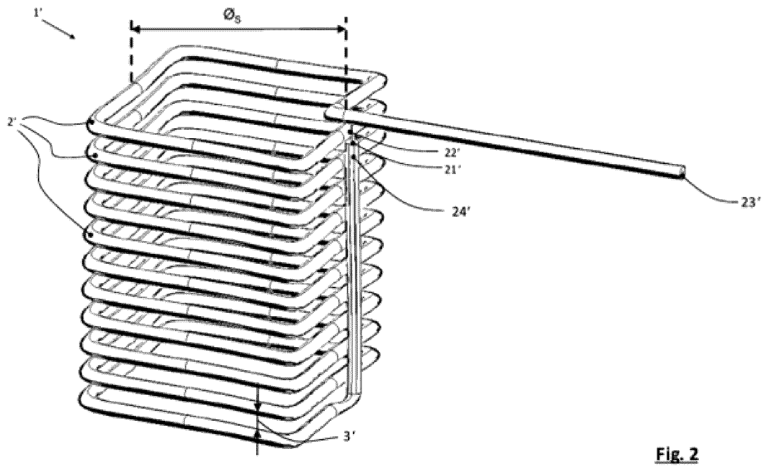

FIG. 2 shows a conceptual illustration of a cable antenna 1′ of a handheld device according to an alternative embodiment of the present invention, wherein the cable antenna 1′ comprises 11 windings 2′. Each winding 2′ exhibits a similar square shape, with a common diameter Øs of less than 30 cm and with a common winding axis. In the embodiment as shown in FIG. 2, a stability provided by the mechanical properties of the cable antenna 1′ is sufficient to maintain a distance 3′ between two adjacent windings 2′, without the necessity of a spacer. As can be gathered from FIG. 2, the distance 3′ is identical or almost identical to the outer diameter of the cable antenna 1′. The cable antenna 1′ is implemented by a coaxial cable comprising, as an outer component, a conductive hull 21′ surrounding an insulating material, in which an inner conductor 22′ is embedded in a centralized manner, as inner core of the coaxial cable. The proximal end 23′ of the cable antenna 1′ is connected to an evaluation unit (not shown) of the handheld device of the presently described alternative embodiment of the present invention. The distal portion of the cable antenna 1′, including its distal end 24′, proceeds towards the proximal portion of the cable antenna 1′, which includes the proximal end 23′, wherein the distal portion of the cable antenna 1′ after concluding the winding progression extends parallel, or at least adjacent, to the winding axis of the windings 2′, with direction towards the proximal portion of the cable antenna 1′. Here, the distal portion of the cable antenna 1′ is arranged at a distance spaced apart from the windings, in order to avoid any contact with the conductive hull 21′ of the cable antenna 1′ in the windings area. At the distal end 24′ of the cable antenna 1′, the inner conductor 22′ then protrudes from the conductive hull 21′ and from the insulating material, and connects to the conductive hull 21′ at a location close to the proximal end 23′ of the cable antenna 1′.

While the current invention has been described in relation to its specific embodiments, it is to be understood that this description is for illustrative purposes only. Accordingly, it is intended that the invention be limited only by the scope of the claims appended hereto.

1. A handheld device for the detection of electrostatic discharge, comprising
an evaluation unit,
a cable antenna (1; 1′) made of a coaxial cable, and
at least one spacer, wherein
the cable antenna (1; 1′) is formed in a coil-like manner with a number n of windings (2; 2′), with n≥2,
each winding (2; 2′) is wound around a winding axis,
a diameter (ØC; ØS) of each winding (2; 2′) is less than 30 cm,
the windings (2; 2′) of the cable antenna (1; 1′) are spaced apart from each other by means of said at least one spacer, and
said at least one spacer is dimensioned to provide for a distance between the windings (2; 2′) residing within a range of 80% to 120% of an outer diameter of the coaxial cable.

2. The handheld device of claim 1, wherein
the number n of windings (2; 2′) is n>2, preferably with 3≤n≤11;
the winding axis is a common winding axis;
a diameter (ØC; ØS) of each winding (2; 2′) is about 5 cm; and/or
diameters (ØC; ØS) of adjacent windings (2; 2′) differ from each other.

3. The handheld device of claim 1, wherein
all windings (2; 2′) exhibit a shape consistent with each other; and/or
a winding shape of the cable antenna (1; 1′) is chosen from the group of shapes consisting of circular, elliptical, triangular, square, polygonal, and a combination thereof.

4. The handheld device of claim 1, wherein
each spacer is made of an insulating material, preferably plastic material, further preferably polyvinylchloride, polypropylene, or polytetrafluoroethylene.

5. The handheld device of claim 1, wherein
the windings (2; 2′) of the cable antenna (1; 1′) are spaced apart from each other by means of at least two spacers, with the two spacers preferably being arranged in an opposing manner, or
the windings (2; 2′) of the cable antenna (1; 1′) are spaced apart from each other by means of at least three spacers, with the spacers preferably being arranged in an equidistant manner.

6. The handheld device of claim 1, wherein the cable antenna (1; 1′) is made of a coaxial cable with an inner conductor comprising silver.

7. The handheld device of claim 1, wherein the evaluation unit comprises
an oscilloscope;
a display;
a wireless communication module; and/or
a network analyzer.

8. The handheld device of claim 1, wherein the handheld device is configured for stationary use with a container.

9. The handheld device of claim 1, wherein the handheld device is adapted for use with a container with a small inner volume, further preferably a container with an inner volume of less than 30 l.

10. The handheld device of claim 1, wherein the handheld device is adapted for measurement in a reactor for chemical production, with the chemical production preferably including processing of suspensions of low conductivity.

11. Use of a handheld device as claimed in claim 1 for the detection of electrostatic discharge in a surrounding containing an explosive atmosphere.

12. Use of a handheld device as claimed in claim 1 for the detection of electrostatic discharge in a container with a volume of less than 30 l, preferably in a reactor for chemical production.

13. Use of a handheld device of claim 11, wherein the handheld device is used for evaluation of a type of electrostatic discharge and the probability of appearance and ignitability of the electrostatic discharges.

14. Use of a handheld device of claim 11, wherein the detection of electrostatic discharge is carried out on demand.

15. Use of a handheld device of claim 11, wherein the detection of electrostatic discharge is carried out continuously, preferably with a sampling rate of 2 μs.
